(19) United States
(12) Patent Application Publication
(10) Pub. No.: US 2025/0212368 A1
(43) Pub. Date: Jun. 26, 2025

(54) HEAT SINK WITH MULTISTAGE PORE CHANNEL STRUCTURE

(71) Applicant: Research & Business Foundation Sungkyunkwan University, Suwon-si (KR)

(72) Inventors: Sung-Min KIM, Suwon-si (KR); Won-Woo CHOI, Suwon-si (KR); Seong-Hwan BANG, Suwon-si (KR); Hong-Cheol SHIN, Suwon-si (KR); Santhosh SENGUTTUVAN, Suwon-si (KR); Seong-Jin AHN, Suwon-si (KR); Seung-Su JEONG, Suwon-si (KR)

(73) Assignee: Research & Business Foundation Sungkyunkwan University, Suwon-si (KR)

(21) Appl. No.: 18/936,998

(22) Filed: Nov. 4, 2024

(30) Foreign Application Priority Data
Dec. 21, 2023 (KR) 10-2023-0188591

(51) Int. Cl. H05K 7/20

(52) U.S. Cl. CPC H05K 7/2039

(57) ABSTRACT

The present invention relates to a heat sink with a multistage pore channel structure and the heat sink includes a main body including an entrance through which a fluid is introduced or discharged and a plurality of channel parts disposed to be stacked in the main body and communicating with the entrance.

### CROSS-REFERENCE TO RELATED APPLICATION

This application claims priority from and the benefit under 35 USC § 119 of Korean Patent Application No. 10-2023-0188591, filed on Dec. 21, 2023, in the Korean Intellectual Property Office, the entire disclosure of which is incorporated by reference for all purposes.

### BACKGROUND

### 1. Field

The present invention relates to a heat sink with a multistage pore channel structure, and more specifically, to the heat sink with the multistage pore channel structure which delays a critical heat flux of pool boiling and improves heat transfer performance.

### 2. Description of the Related Art

Generally, a heat sink is one type of heat exchanger and is an apparatus which distributes heat generated by a component throughout the heat sink to suppress heating of the component.

In conventional heat sinks, various technologies of adhering copper or aluminum foam to a heating surface or using a nano fluid, artificial pores, and a pore having a lower channel having one closed end have been used in order to improve of heat transfer performance.

However, when copper or aluminum foam is adhered to a heating surface or a nano fluid is used, there is a problem that a risk of heat loss due to contamination can occur. In addition, when a surface having a channel having one closed end is used as a heat sink, there is a problem that the performance of the heat sink is degraded because the surface becomes a target of flooding in the range from a low heat flux to a medium heat flux or a dry phenomenon occurs in a high heat flux.

In order to solve such problems, a heat sink having an open multistage channel including a pore needs to be developed to prevent flooding and improve fluid diffusion.

The related art of the present invention is disclosed in Korean Patent Publication No. 10-1388845 (Published on Oct. 30, 2014, Invention Title: Cooling system having multi-stage heat sink and method for controlling the same).

### SUMMARY OF THE INVENTION

The present invention is directed to providing a heat sink with a multistage pore channel structure, which delays a critical heat flux of pool boiling and improves heat transfer performance.

According to an aspect of the present invention, there is provided the heat sink with the multistage pore channel structure including a main body including an entrance through which a fluid is introduced or discharged and a plurality of channel parts disposed to be stacked in the main body and communicating with the entrance.

The channel parts may include a first channel part which is provided inside the main body and through which the fluid flows and a second channel part which is provided inside the main body and disposed to be stacked with the first channel part and through which the fluid flows.

The first channel part may extend in a first direction, and the second channel part may extend in a second direction intersecting the first direction.

The main body may include an opening through which the first channel part is exposed.

The entrance may include a first entrance which communicates with the first channel part and through which the fluid flows and a second entrance which is disposed to face the first entrance and communicates with the first channel part and the second channel part and through which the fluid flows.

The first channel part may include a first port through which the fluid is introduced or discharged, and the first port may be disposed at one side or each of both sides of the first channel part.

The first channel part may include a plurality of first channels disposed apart from each other in a first direction and a plurality of second channels disposed apart from each other in a second direction intersecting the first direction and communicating with the plurality of first channels.

The first entrance may be located at a first intersection part at which each of the plurality of the first channels intersects one of the plurality of second channels.

The first entrance may be provided as a plurality of first entrances disposed apart from each other in the first direction and the second direction at the first intersection part.

The second channel part may include a second port through which the fluid is introduced or discharged, and the second port may be disposed at one side or each of both sides of the second channel part.

Vapor bubbles generated in the first channel part and the second channel part may be discharged through the first port, the second port, or the entrance.

The second channel part may include a plurality of third channels disposed apart from each other in the first direction and a plurality of fourth channels disposed apart from each other in the second direction intersecting the first direction and communicating with the plurality of third channels.

A cross section of each of the first channel, the second channel, the third channel, and the fourth channel may be formed in any one shape of a circular shape, an oval shape, and a polygonal shape.

The second entrance may be disposed at a second intersection part at which each of the plurality of third channels intersects one of the plurality of fourth channels.

The second entrance may be provided as a plurality of second entrances disposed apart from each other in the first direction and the second direction at the second intersection part.

The third channel may include a plurality of first pin fin parts disposed apart from each other in the second direction, and the fourth channel may include a plurality of second pin fin parts disposed apart from each other in the first direction.

A diameter of the second entrance may be smaller than a diameter of the first entrance.

The second entrance may be provided as a plurality of second entrances in a range limited by the diameter of the first entrance.

The first entrance may be provided in a first surface of the main body, and a heat spreader may be coupled to a second surface of the main body.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view illustrating a heat sink with a multistage pore channel structure according to a first embodiment of the present invention;

FIG. 2 is a partial cross-sectional perspective view illustrating the heat sink with the multistage pore channel structure according to the first embodiment of the present invention;

FIG. 3 is a bottom perspective view illustrating the heat sink with the multistage pore channel structure according to the first embodiment of the present invention;

FIG. 4 is a partial cross-sectional perspective view illustrating an inner portion of a heat sink with a multistage pore channel structure according to a second embodiment of the present invention;

FIG. 5 is a plan view illustrating the heat sink with the multistage pore channel structure according to the second embodiment of the present invention;

FIG. 6 is a perspective view illustrating a heat sink with a multistage pore channel structure according to a third embodiment of the present invention;

FIG. 7 is a partial cross-sectional perspective view illustrating an inner portion of the heat sink with the multistage pore channel structure according to the third embodiment of the present invention;

FIG. 8 is an exemplary view illustrating a flow of a fluid in the heat sink with the multistage pore channel structure according to the third embodiment of the present invention;

FIGS. 9 and 10 are exemplary views illustrating a state in which a plurality of channel parts are stacked in a main body in the heat sink with the multistage pore channel structure according to the third embodiment of the present invention;

FIG. 11 is a partial cross-sectional perspective view illustrating an inner portion of a heat sink with a multistage pore channel structure according to a fourth embodiment of the present invention;

FIG. 12 is a side cross-sectional view illustrating the heat sink with the multistage pore channel structure according to the fourth embodiment of the present invention;

FIGS. 13 to 16 are perspective views illustrating an example of a channel part in a heat sink with a multistage pore channel structure according to an embodiment of the present invention;

FIG. 17 is a perspective view illustrating a heat sink with a multistage pore channel structure according to a fifth embodiment of the present invention;

FIG. 18 is a partial cross-sectional perspective view illustrating an inner portion of the heat sink with the multistage pore channel structure according to the fifth embodiment of the present invention;

FIG. 19 is a perspective view illustrating a heat sink with a multistage pore channel structure according to a sixth embodiment of the present invention; and

FIG. 20 is a partial cross-sectional perspective view illustrating an inner portion of the heat sink with the multistage pore channel structure according to the sixth embodiment of the present invention.

### DETAILED DESCRIPTION

Hereinafter, embodiments of a heat sink with a multistage pore channel structure according to the present invention will be described with reference to the accompanying drawings. During the description, thicknesses of lines, sizes of components, or the like illustrated in the drawings may be exaggerated for clarity and convenience of the description. In addition, some terms described below are defined in consideration of functions in the present invention and may vary depending on a user or operator's intentions or customs. Therefore, the definitions of the terms should be determined based on the content throughout the present specification.

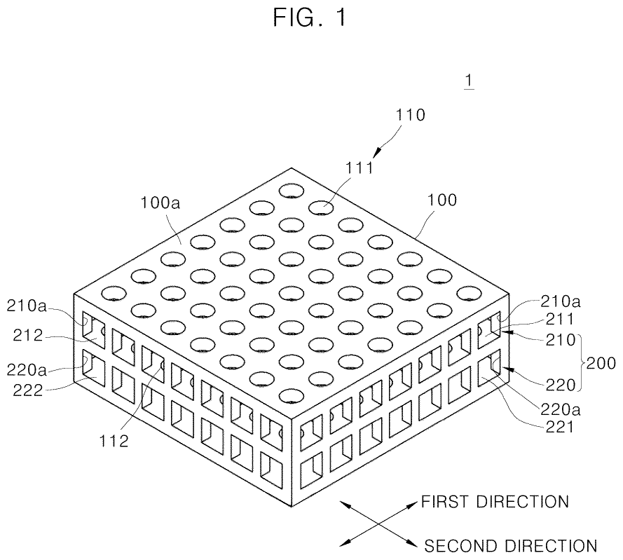

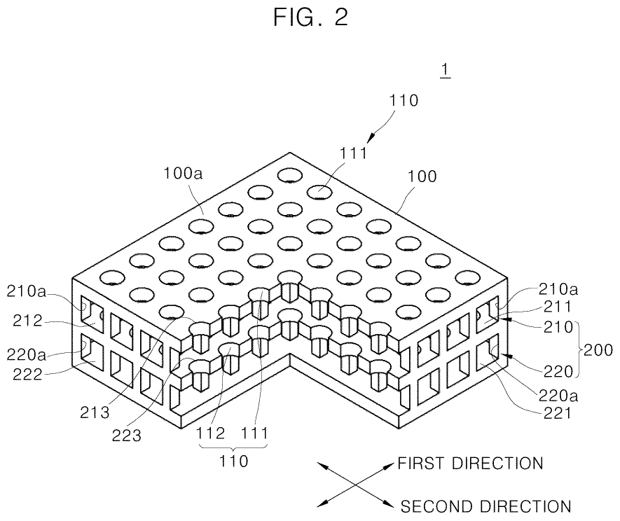

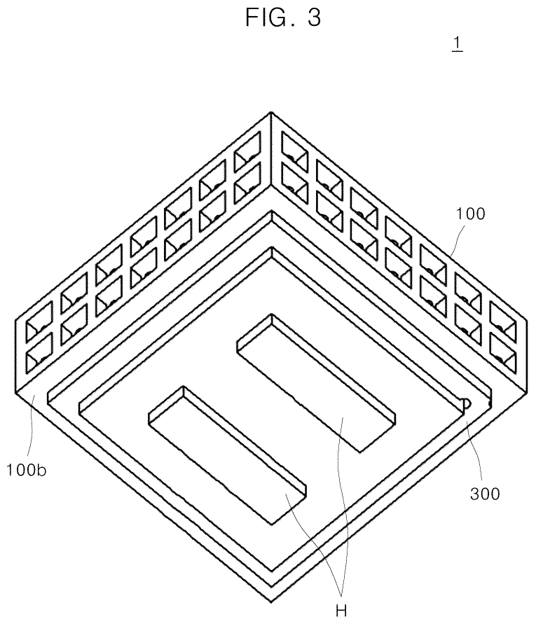

FIG. 1 is a perspective view illustrating a heat sink with a multistage pore channel structure according to a first embodiment of the present invention, FIG. 2 is a partial cross-sectional perspective view illustrating the heat sink with the multistage pore channel structure according to the first embodiment of the present invention, and FIG. 3 is a bottom perspective view illustrating the heat sink with the multistage pore channel structure according to the first embodiment of the present invention.

Referring to FIGS. 1 to 3, a heat sink 1 with a multistage pore channel structure according to the first embodiment of the present invention may include a main body 100 and a channel part 200.

The main body 100 may form an exterior of the heat sink 1 with the multistage pore channel structure of the present invention and may be disposed outside a fluid, or the entirety or a portion of the main body 100 may be immersed in the fluid. In this case, an example of the fluid may be a cooling oil.

The main body 100 may include an entrance 110 through which a fluid is introduced or discharged. The entrance 110 may serve as a passage through which a fluid is introduced into the main body 100 or a fluid inside the main body 100 is discharged to the outside of the main body 100. The entrance 110 may be formed in a hole shape passing through the main body 100.

The channel part 200 may be provided as a plurality of channel parts 200 and disposed to be stacked in the main body 100. The channel part 200 may be stacked in a height direction of the main body 100. In other words, the plurality of channel parts 200 may be disposed apart from each other in the height direction of the main body 100.

The plurality of channel parts 200 may communicate with the entrance 110. The channel parts 200 may include a first channel part 210 and a second channel part 220.

The first channel part 210 may be provided inside the main body 100. A fluid may flow through the first channel part 210. The first channel part 210 may include a first port 210a. The first port 210a may be disposed at one side or each of both sides of the first channel part 210. The fluid may be introduced into the first channel part 210 or discharged to the outside of first channel part 210 through the first port 210a. The first channel part 210 may include a first channel 211 and a second channel 212.

A plurality of first channels 211 may be disposed apart from each other in a first direction. The first channel 211 may extend in a second direction intersecting the first direction.

A cross section of the first channel 211 may be formed in any one shape of a circular shape, an oval shape, and a polygonal shape. The cross section of the first channel 211 according to the first embodiment of the present invention may be formed in a quadrangular shape.

A plurality of second channels 212 may be disposed apart from each other in the second direction intersecting the first direction. The second channels 212 may extend in the first direction intersecting the second direction. The plurality of first channels 211 and the plurality of second channels 212 may communicate with each other.

A cross section of the second channel 212 may be formed in any one shape of a circular shape, an oval shape, and a polygonal shape. The cross section of the second channel 212 according to the first embodiment of the present invention may be formed in a quadrangular shape.

The second channel part 220 may be provided inside the main body 100. The second channel part 220 may be disposed to be stacked with the first channel part 210. A fluid may flow through the second channel part 220. The second channel part 220 may include a second port 220a. The second port 220a may be disposed at one side or each of both sides of the second channel part 220. A fluid may be introduced into the second channel part 220, or discharged to the outside of the second channel part 220 through the second port 220a. The second channel part 220 may include a third channel 221 and a fourth channel 222.

A plurality of third channels 221 may be disposed apart from each other in the first direction. The third channels 221 may extend in the second direction intersecting the first direction.

A cross section of the third channel 221 may be formed in any one shape of a circular shape, an oval shape, and a polygonal shape. The cross section of the third channel 221 according to the first embodiment of the present invention may be formed in a quadrangular shape.

A plurality of fourth channels 222 may be disposed apart from each other in the second direction intersecting the first direction. The fourth channels 222 may extend in the first direction intersecting the second direction. The plurality of third channels 221 and the plurality of fourth channels 222 may communicate with each other.

A cross section of the fourth channel 222 may be formed in any one shape of a circular shape, an oval shape, and a polygonal shape. The cross section of the fourth channel 222 according to the first embodiment of the present invention may be formed in a quadrangular shape.

The entrance 110 according to the first embodiment of the present invention may include a first entrance 111 and a second entrance 112.

The first entrance 111 may communicate with the first channel part 210 to allow a fluid to flow therethrough. The first entrance 111 may be provided in a first surface 100a of the main body 100. The first entrance 111 may be formed to pass through the first surface 100a of the main body 100. The first entrance 111 may be formed in the height direction of the main body 100.

The first entrance 111 may be located at a first intersection part 213 at which each of the plurality of first channels 211 intersects one of the plurality of second channels 212. Accordingly, a plurality of first entrances 111 may be disposed apart from each other in the first direction and the second direction.

The second entrance 112 may be provided inside the main body 100. The second entrance 112 may be formed in the height direction of the main body 100. The second entrance 112 may be disposed to face the first entrance 111.

The second entrance 112 may be formed to pass between the first channel part 210 and the second channel part 220. The second entrance 112 may communicate with the first channel part 210 and the second channel part 220 to allow the fluid to flow therethrough.

The second entrance 112 may be located at a second intersection part 223 at which each of the plurality of third channels 221 intersects one of the plurality of fourth channels 222. Accordingly, a plurality of second entrances 112 may be disposed apart from each other in the first direction and the second direction.

The heat sink 1 with the multistage pore channel structure according to the first embodiment of the present invention may further include a heat spreader 300.

The heat spreader 300 may be coupled to a second surface 100b of the main body 100. The heat spreader 300 may be in contact with a heat source H such as an integrated circuit which is an electronic component and may serve to transfer heat generated by the heat source H to the main body 100.

Vapor bubbles generated in the first channel part 210 and the second channel part 220 may be discharged through the first port 210a, the second port 220a, or the entrance 110. In other words, when a fluid is heated by the heat source H, and a fluid is introduced through the entrance 110 at the same time, vapor bubbles generated due to the heating may be discharged to the outside of the main body 100 through the first port 210a and the second port 220a.

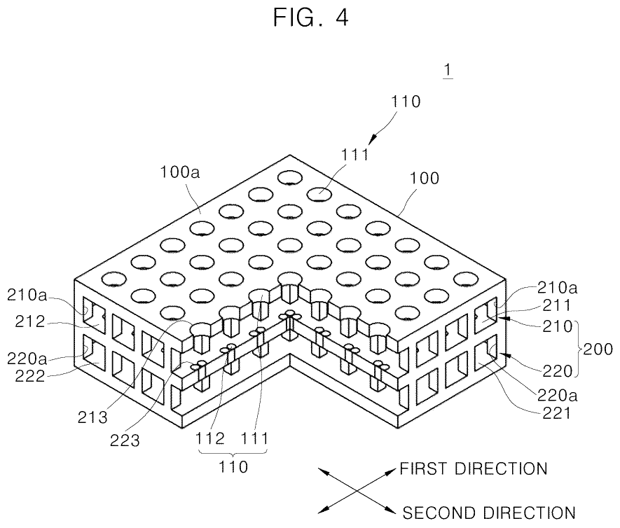

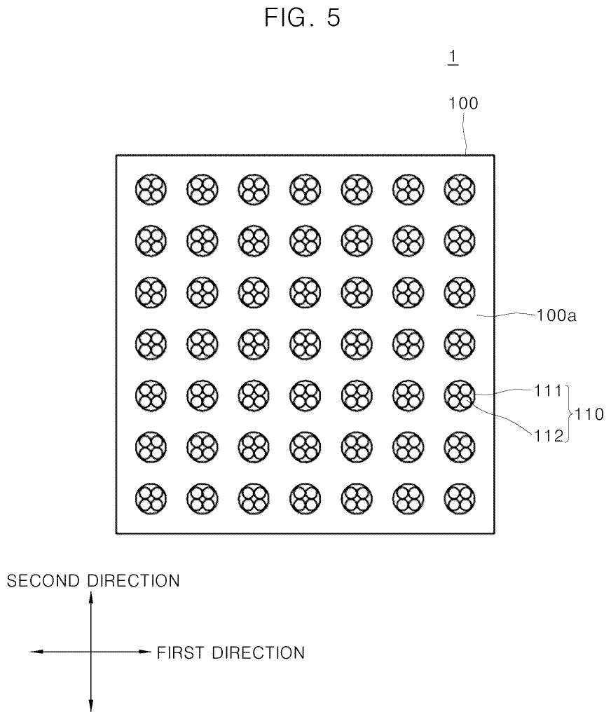

That is, the main body 100 may be immersed in a fluid (nonconductive liquid), and when the heat source H is heated, the main body 100 may be heated, and boiling may occur on a surface of the main body 100. In this case, vapor bubbles generated in the boiling process may move to the entrance 110 due to their buoyancy. FIG. 4 is a partial cross-sectional perspective view illustrating an inner portion of a heat sink with a multistage pore channel structure according to a second embodiment of the present invention, and FIG. 5 is a plan view illustrating the heat sink with the multistage pore channel structure according to the second embodiment of the present invention.

Referring to FIGS. 4 and 5, the heat sink 1 with the multistage pore channel structure according to the second embodiment of the present invention may include a main body 100 and a channel part 200.

In the description of the heat sink 1 with the multistage pore channel structure according to the second embodiment of the present invention, only another example of the entrance 110 which is different from that of the heat sink 1 with the multistage pore channel structure according to the first embodiment of the present invention will be described.

The descriptions of the heat sink 1 with the multistage pore channel structure according to the first embodiment of the present invention may be applied to the other components of the heat sink 1 with the multistage pore channel structure according to the second embodiment of the present invention without change.

A second entrance 112 according to the second embodiment of the present invention may be formed to have a diameter smaller than a diameter of a first entrance 111. The second entrance 112 may be provided as a plurality of second entrances 122 in a range limited by the diameter of the first entrance 111. For example, when one first entrance 111 is provided in a first intersection part 213, four second entrances 112 may be provided in a first direction and a second direction in a second intersection part 223.

A flow of a fluid in the main body 100 may be changed and a critical heat flux may be changed by differentiating the diameter of the first entrance 111 from the diameter of the second entrance 112.

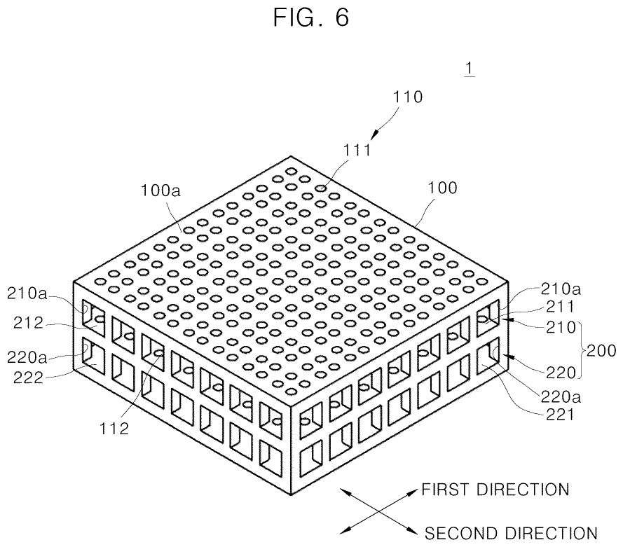

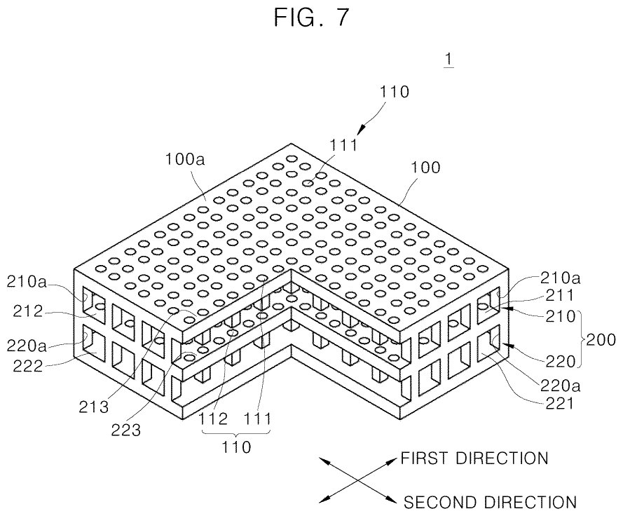

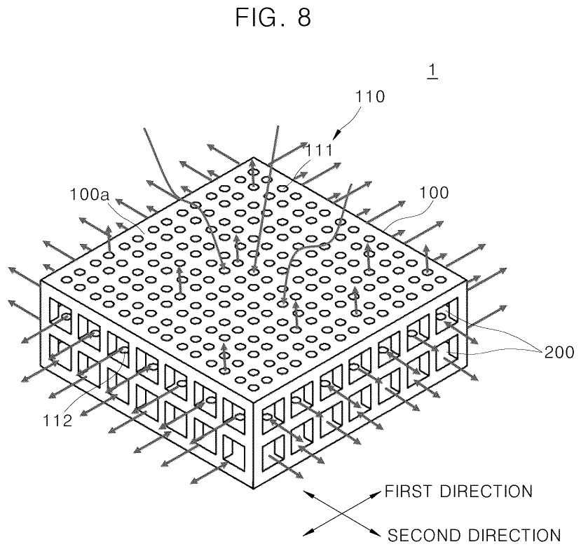

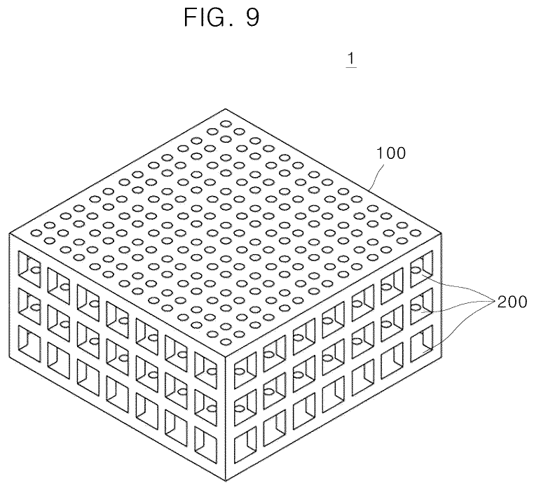

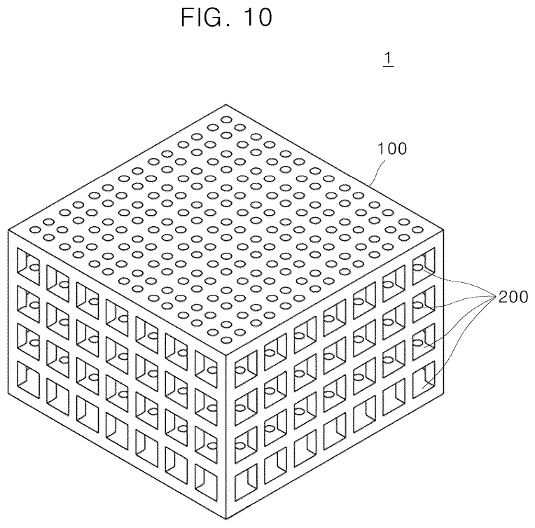

FIG. 6 is a perspective view illustrating a heat sink with a multistage pore channel structure according to a third embodiment of the present invention, and FIG. 7 is a partial cross-sectional perspective view illustrating an inner portion of the heat sink with the multistage pore channel structure according to the third embodiment of the present invention. FIG. 8 is an exemplary view illustrating a flow of a fluid in the heat sink with the multistage pore channel structure according to the third embodiment of the present invention, and FIGS. 9 and 10 are exemplary views illustrating a state in which a plurality of channel parts are stacked in a main body in the heat sink with the multistage pore channel structure according to the third embodiment of the present invention;

Referring to FIGS. 6 to 10, a heat sink 1 with a multistage pore channel structure according to the third embodiment of the present invention may include a main body 100 and a channel part 200.

In the description of the heat sink 1 with the multistage pore channel structure according to the third embodiment of the present invention, another example of the channel part 200 and still another example of the entrance 110 different from those of the heat sink 1 with the multistage pore channel structure according to the first embodiment or the second embodiment of the present invention will be described.

The descriptions of the heat sink 1 with the multistage pore channel structure according to the first embodiment or the second embodiment of the present invention may be applied to the other components of the heat sink 1 with the multistage pore channel structure according to the third embodiment of the present invention without change.

The channel part 200 according to the third embodiment of the present invention may be provided as a plurality of channel parts 200 and provided to be stacked in the main body 100. The channel parts 200 may be stacked in a height direction of the main body 100. In other words, the plurality of channel parts 200 may be disposed apart from each other in the height direction of the main body 100.

For example, a third channel part and a fourth channel part may be disposed in the height direction of the main body 100 in addition to a first channel parts 210 and second channel parts 220 which are disposed to be stacked in the height direction of the main body 100. Accordingly, a heat source H of a high output power electronic device can be effectively cooled.

A first entrance 111 according to the third embodiment of the present invention may be located at a first intersection part 213 at which each of a plurality of first channels 211 intersects one of a plurality of second channels 212. The first entrance 111 may be provided as a plurality of first entrances 111 at the first intersection parts 213. In other words, the plurality of first entrances 111 may be disposed apart from each other at the first intersection part 213 in a first direction and a second direction.

A second entrance 112 according to the third embodiment of the present invention may be located at a second intersection part 223 at which each of a plurality of third channels 221 intersect one of a plurality of fourth channels 222. The second entrance 112 may be provided as a plurality of second entrances 112 at the second intersection part 223. In other words, the plurality of second entrances 112 may be disposed apart from each other at the second intersection part 223 in the first direction and the second direction.

For example, when four first entrances 111 disposed in the first direction and the second direction are provided at the first intersection part 213, four second entrances 112 disposed in the first direction and the second direction may be provided at the second intersection part 223.

A fluid introduced into the main body 100 may be heated by a heat source H, and vapor bubbles may be generated in the fluid in this process. The vapor bubbles may be discharged to the outside through the first channel part 210 and the second channel part 220 so that heat exchange with the fluid can be actively performed. In other words, the heated fluid may generate the vapor bubbles in the first channel part 210 and the second channel part 220. The vapor bubbles may be discharged to the outside of the main body 100 through a first port 210a, a second port 220a, or the entrance 110.

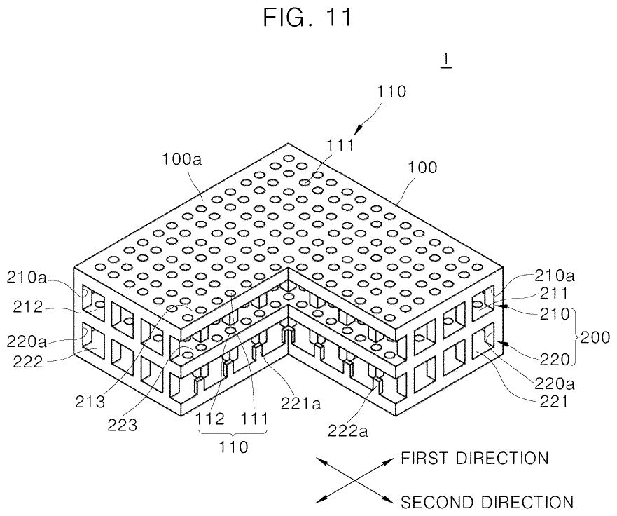

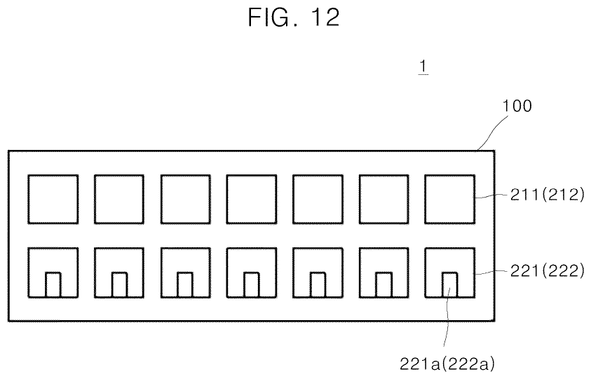

FIG. 11 is a partial cross-sectional perspective view illustrating an inner portion of a heat sink with a multistage pore channel structure according to a fourth embodiment of the present invention, and FIG. 12 is a side cross-sectional view illustrating the heat sink with the multistage pore channel structure according to the fourth embodiment of the present invention.

Referring to FIGS. 11 and 12, a heat sink 1 with a multistage pore channel structure according to the fourth embodiment of the present invention may include a main body 100 and a channel part 200.

In the description of the heat sink 1 with the multistage pore channel structure according to the fourth embodiment of the present invention, only still another example of the channel part 200 which is different from that of the heat sink 1 with the multistage pore channel structure according to the first embodiment, the second embodiment, or the third embodiment of the present invention will be described.

The descriptions of the heat sink 1 with the multistage pore channel structure according to the first embodiment, the second embodiment, or the third embodiment of the present invention may be applied to the other components of the heat sink 1 with the multistage pore channel structure according to the fourth embodiment of the present invention without change.

A second channel part 220 according to the fourth embodiment of the present invention may include a first pin fin part 221a and a second pin fin part 222a. In other words, a third channel 221 may include the first pin fin part 221a, and a fourth channel 222 may include the second pin fin part 222a.

A plurality of first pin fin parts 221a may be disposed apart from each other in a second direction. The first pin fin part 221a may be disposed on a central portion of the third channel 221 and formed to protrude from a bottom of the third channel 221 in a height direction of the main body 100. A cross section of the first pin fin part 221a may be formed in a quadrangular shape.

A plurality of second pin fin parts 222a may be disposed apart from each other in a first direction. The second pin fin parts 222a may be disposed in a central portion of the fourth channel 222 and formed to protrude from a bottom of the fourth channel 222 in the height direction of the main body 100. A cross section of the second pin fin part 222a may be formed in a quadrangular shape.

As the first pin fin part 221a and the second pin fin part 222a are formed on the second channel part 220, an area of heat exchange may change, and a flow of a fluid flowing in the main body 100 may change.

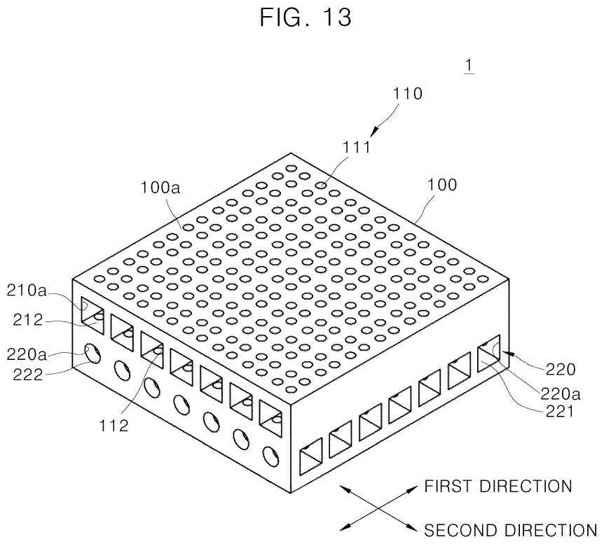

FIGS. 13 to 16 are perspective views illustrating an example of a channel part in a heat sink with a multistage pore channel structure according to an embodiment of the present invention.

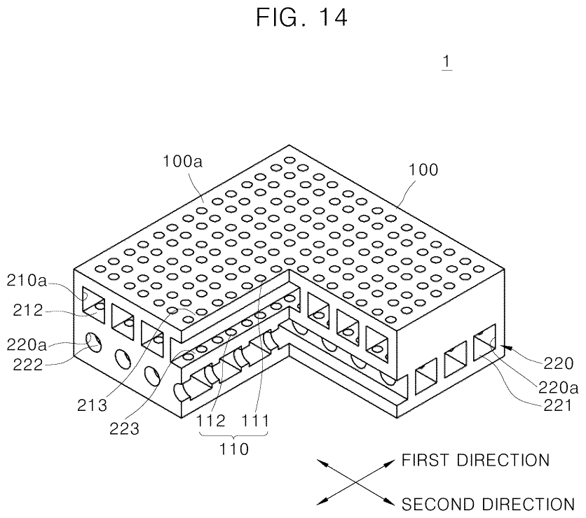

Referring to FIGS. 13 and 14, a first channel part 210 may include only a second channel 212 and no first channel 211. A plurality of second channels 212 may be disposed apart from each other in a second direction intersecting a first direction. The second channels 212 may extend in the first direction intersecting the second direction.

A cross section of the second channel 212 may be formed in any one shape of a circular shape, an oval shape, and a polygonal shape. In other words, the cross section of the second channel 212 may be formed in a quadrangular shape.

The second channel part 220 may include a third channel 221 and a fourth channel 222. A plurality of third channels 221 may be disposed apart from each other in the first direction. The third channels 221 may extend in the second direction intersecting the first direction.

A cross section of the third channel 221 may be formed in any one shape of a circular shape, an oval shape, and a polygonal shape. In other words, the cross section of the third channel 221 may be formed in a quadrangular shape.

A plurality of fourth channels 222 may be disposed apart from each other in the second direction intersecting the first direction. The fourth channels 222 may extend in the first direction intersecting the second direction. The plurality of third channels 221 and the plurality of fourth channels 222 may communicate with each other.

A cross section of the fourth channel 222 may be formed in any one shape of a circular shape, an oval shape, and a polygonal shape. In other words, the cross section of the fourth channel 222 may be formed in a circular shape. As described above, a shape of a cross section of the channel part 200 may change in consideration of a cooling environment and properties of a fluid.

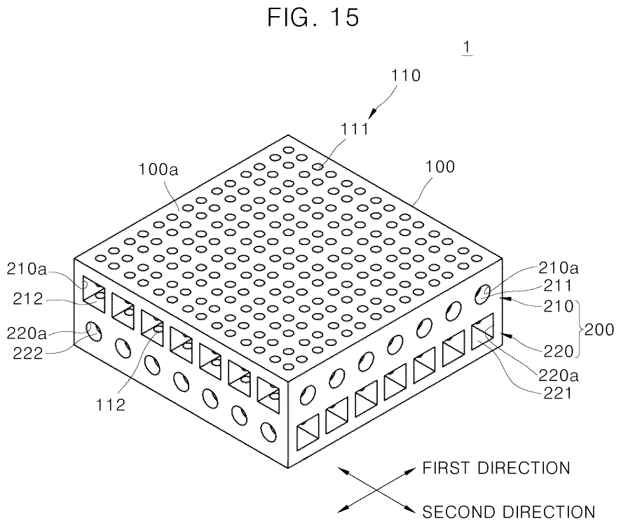

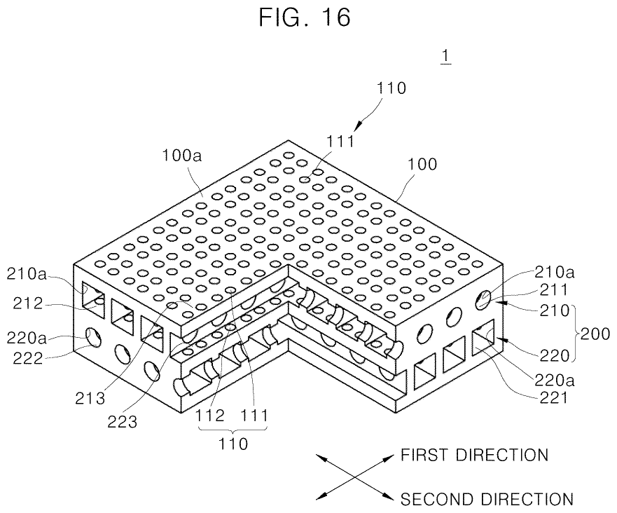

Referring to FIGS. 15 and 16, a first channel part 210 may include a first channel 211 and a second channel 212.

A plurality of first channels 211 may be disposed apart from each other in a first direction. The first channels 211 may extend in a second direction intersecting the first direction.

A cross section of the first channel 211 may be formed in any one shape of a circular shape, an oval shape, and a polygonal shape. In other words, the cross section of the first channel 211 may be formed in a circular shape.

A plurality of second channels 212 may be disposed apart from each other in the second direction intersecting the first direction. The second channels 212 may extend in the first direction intersecting the second direction. The plurality of first channels 211 and the plurality of second channels 212 may communicate with each other.

A cross section of the second channel 212 may be formed in any one shape of a circular shape, an oval shape, and a polygonal shape. In other words, the cross section of the second channel 212 may be formed in a quadrangular shape.

A second channel part 220 may include a third channel 221 and a fourth channel 222. A plurality of third channels 221 may be disposed apart from each other in the first direction. The third channels 221 may extend in the second direction intersecting the first direction.

A cross section of third channels 221 may be formed in any one shape of a circular shape, an oval shape, and a polygonal shape. In other words, the cross section of the third channel 221 may be formed in a quadrangular shape.

A plurality of fourth channels 222 may be disposed apart from each other in the second direction intersecting the first direction. The fourth channels 222 may extend in the first direction intersecting the second direction. The plurality of third channels 221 and the plurality of fourth channels 222 may communicate with each other.

A cross section of the fourth channel 222 may be formed in any one shape of a circular shape, an oval shape, and a polygonal shape. In other words, the cross section of the fourth channel 222 may be formed in a circular shape. As described above, a shape of a cross section of the channel part 200 may change in consideration of a cooling environment and properties of a fluid.

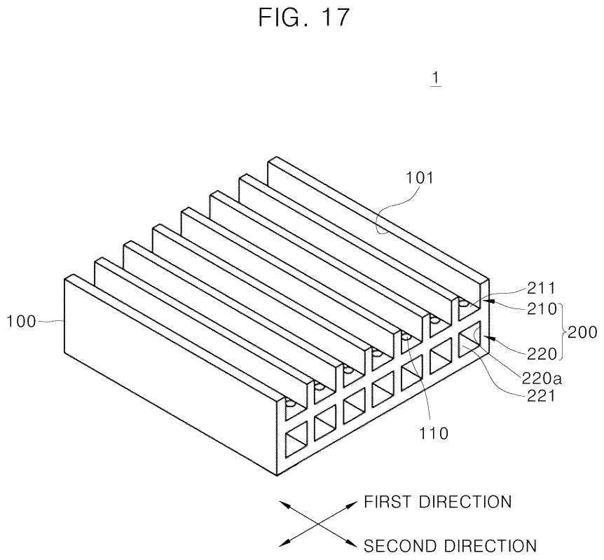

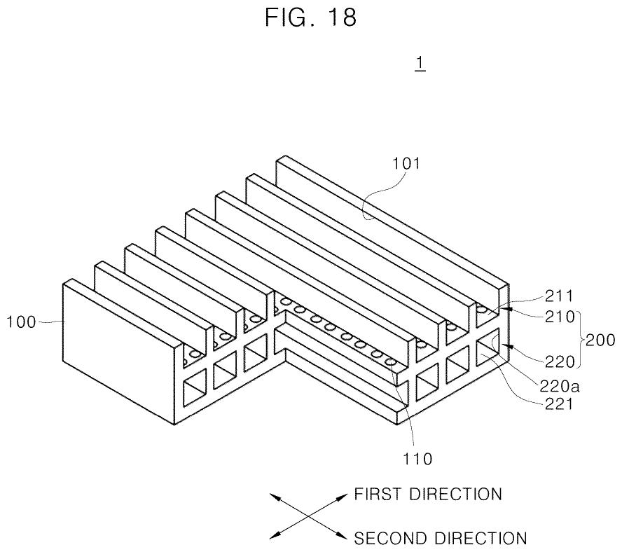

FIG. 17 is a perspective view illustrating a heat sink with a multistage pore channel structure according to a fifth embodiment of the present invention, and FIG. 18 is a partial cross-sectional perspective view illustrating an inner portion of the heat sink with the multistage pore channel structure according to the fifth embodiment of the present invention.

Referring to FIGS. 17 and 18, a heat sink 1 with a multistage pore channel structure according to the fifth embodiment of the present invention may include a main body 100 and a channel part 200.

The main body 100 may include an entrance 110 through which a fluid is introduced or discharged. The entrance 110 may serve as a passage through which a fluid is introduced into the main body 100 or a fluid in the main body 100 is discharged to the outside of the main body 100. The entrance 110 may be formed in a hole shape passing through the main body 100.

The channel part 200 may be provided as a plurality of channel parts 200 and disposed to be stacked in the main body 100. The channel parts 200 may be stacked in a height direction of the main body 100. In other words, the plurality of channel parts 200 may be disposed apart from each other in the height direction of the main body 100.

The plurality of channel parts 200 may communicate with the entrance 110. The channel part 200 may include a first channel part 210 and a second channel part 220. The first channel part 210 may be provided inside the main body 100. A fluid may flow through the first channel part 210.

The first channel part 210 according to the fifth embodiment of the present invention may include a plurality of first channels 211 disposed apart from each other in a first direction. The first channels 211 may extend in a second direction intersecting the first direction.

The second channel part 220 may be provided inside the main body 100. The second channel part 220 may be disposed to be stacked with the first channel part 210. A fluid may flow through the second channel part 220.

The second channel part 220 according to the fifth embodiment of the present invention may include a second port 220a. The second port 220a may be disposed at one side or each of both sides of the second channel part 220. The fluid may be introduced into the second channel part 220 or discharged to the outside of the second channel part 220 through the second port 220a.

The second channel part 220 according to the fifth embodiment of the present invention may include a plurality of third channels 221 disposed apart from each other in the first direction. The third channels 221 may extend in the second direction intersecting the first direction.

A cross section of the third channel 221 may be formed in any one shape of a circular shape, an oval shape, and a polygonal shape. The cross section of the third channel 221 according to the fifth embodiment of the present invention may be formed in a quadrangular shape.

The main body 100 according to the fifth embodiment of the present invention may include an opening 101. The opening 101 may be provided in one outer surface (an upper surface based on FIG. 17) of the main body 100. The opening 101 may be formed to pass through one outer surface of the main body 100. The first channel part 210 may be exposed through the opening 101. Accordingly, both sidewalls of the first channel 211 may be used as pin fins.

The entrance 110 according to the fifth embodiment of the present invention may be provided inside the main body 100. The entrance 110 may be formed in the height direction of the main body 100. The entrance 110 may be formed to pass between the first channel part 210 and the second channel part 220. The entrance 110 may communicate with the first channel part 210 and the second channel part 220 to allow a fluid to flow therethrough. A plurality of entrances 110 may be disposed apart from each other in the second direction.

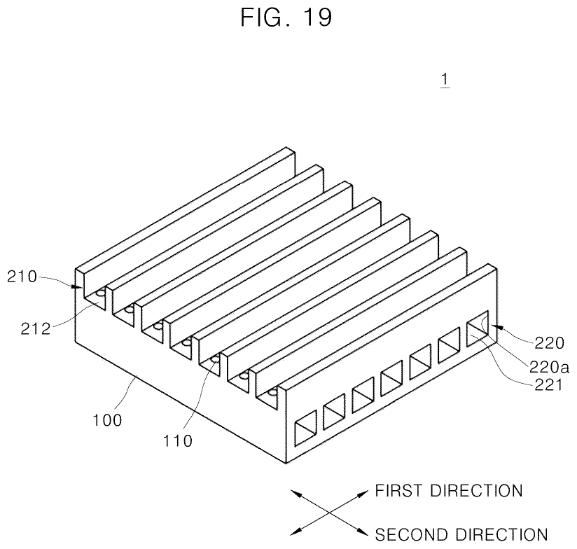

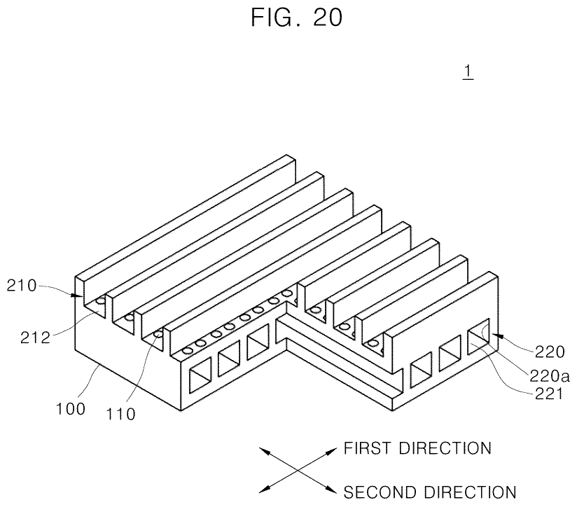

FIG. 19 is a perspective view illustrating a heat sink with a multistage pore channel structure according to a sixth embodiment of the present invention, and FIG. 20 is a partial cross-sectional perspective view illustrating an inner portion of the heat sink with the multistage pore channel structure according to the sixth embodiment of the present invention.

Referring to FIGS. 19 and 20, a heat sink 1 with a multistage pore channel structure according to the sixth embodiment of the present invention may include a main body 100 and a channel part 200.

The main body 100 may include an entrance 110 through which a fluid is introduced or discharged. The entrance 110 may serve as a passage through which a fluid is introduced into the main body 100, or a fluid inside the main body 100 is discharged to the outside of the main body 100. The entrance 110 may be formed in a hole shape passing through the main body 100.

The channel part 200 may be provided as a plurality of channel parts 200 and disposed to be stacked in the main body 100. The channel parts 200 may be stacked in a height direction of the main body 100. In other words, the plurality of channel parts 200 may be disposed apart from each other in the height direction of the main body 100.

The plurality of channel parts 200 may communicate with the entrance 110. The channel part 200 may include a first channel part 210 and a second channel part 220. The first channel part 210 may be provided inside the main body 100. A fluid may flow through the first channel part 210. The first channel part 210 may extend in a first direction.

The first channel part 210 according to the sixth embodiment of the present invention may include a plurality of second channels 212 disposed apart from each other in a second direction intersecting the first direction. The second channels 212 may extend in the first direction.

The second channel part 220 may be provided inside the main body 100. The second channel part 220 may be disposed to be stacked with the first channel part 210. A fluid may flow through the second channel part 220.

The second channel part 220 according to the sixth embodiment of the present invention may include a second port 220a. The second port 220a may be disposed at one side or each of both sides of the second channel part 220. The fluid may be introduced into the second channel part 220 or discharged to the outside of the second channel part 220 through the second port 220a.

The second channel part 220 according to the sixth embodiment of the present invention may extend in the second direction. The second channel part 220 may include a plurality of third channels 221 disposed apart from each other in the first direction. The third channels 221 may extend in the second direction.

A cross section of the third channel 221 may be formed in any one shape of a circular shape, an oval shape, and a polygonal shape. The cross section of the third channel 221 according to the sixth embodiment of the present invention may be formed in a quadrangular shape.

The main body 100 according to the sixth embodiment of the present invention may include an opening. An opening 101 may be provided in one outer surface (an upper surface based on FIG. 19) of the main body 100. The opening 101 may be formed to pass through one outer surface of the main body 100. The first channel part 210 may be exposed through the opening 101. Accordingly, both sidewalls of the first channel 211 may be used as pin fins.

The entrance 110 according to the sixth embodiment of the present invention may be provided inside the main body 100. The entrance 110 may be formed in the height direction of the main body 100. The entrance 110 may be formed to pass between the first channel part 210 and the second channel part 220. The entrance 110 may communicate with the first channel part 210 and the second channel part 220 to allow a fluid to flow therethrough. A plurality of entrances 110 may be disposed apart from each other in the first direction.

Since the heat sink 1 with the multistage pore channel structure according to the embodiment of the present invention includes the multistage channel part 200 having one of various shapes, a heat transfer region can be wide and a nucleation site density can be high when compared to the conventional heat sink.

Since a heat transfer rate of the heat sink 1 with the multistage pore channel structure according to the embodiment of the present invention is higher than that of a surface of the conventional heat sink having a channel with one closed side end, entering a critical heat flux can be delayed.

Since the heat sink 1 with the multistage pore channel structure according to the embodiment of the present invention is provided with a multistage channel structure which responds to a high heat flux, the heat sink 1 with the multistage pore channel structure can be applied to cooling of an electronic device requiring a high output power.

The heat sink 1 with the multistage pore channel structure according to the embodiment of the present invention can lower a temperature of a surface of the heat source H when compared to the conventional heat sink in addition to obtaining a higher critical heat flux value in pool boiling heat transfer.

Since the present invention includes a multistage channel part having one of various shapes, there are effects that a heat transfer region is wide and a nucleation site density is high when compared to the conventional heat sink.

In addition, since the present invention has a high heat transfer rate when compared to a surface of the conventional heat sink having a channel having one closed side end, there is an effect that entering a critical heat flux is delayed.

In addition, since the present invention includes a multistage channel structure capable of responding a high heat flux, there is an effect of being used in cooling of an electronic device requiring high output power.

In addition, in the present invention, there is an effect of lowering a temperature of a surface of a heat source when compared to the conventional heat sink in addition to obtaining a higher critical heat flux value in pool boiling heat transfer.

While the present invention has been described with reference to embodiments illustrated in the accompanying drawings, the embodiments should be considered in a descriptive sense only, and it should be understood that various alterations and equivalent other embodiments may be made by those skilled in the art. Therefore, the scope of the invention should be defined by the appended claims.

What is claimed is:

1. A heat sink with a multistage pore channel structure, comprising:
a main body including an entrance through which a fluid is introduced or discharged; and
a plurality of channel parts disposed to be stacked in the main body and communicating with the entrance.

2. The heat sink of claim 1, wherein the channel parts include:
a first channel part which is provided inside the main body and through which the fluid flows; and
a second channel part which is provided inside the main body and disposed to be stacked with the first channel part and through which the fluid flows.

3. The heat sink of claim 2, wherein:
the first channel part extends in a first direction; and
the second channel part extends in a second direction intersecting the first direction.

4. The heat sink of claim 3, wherein the main body includes an opening through which the first channel part is exposed.

5. The heat sink of claim 2, wherein the entrance includes:
a first entrance which communicates with the first channel part and through which the fluid flows; and
a second entrance which is disposed to face the first entrance and communicates with the first channel part and the second channel part and through which the fluid flows.

6. The heat sink of claim 5, wherein:
the first channel part includes a first port through which the fluid is introduced or discharged; and
the first port is disposed at one side or each of both sides of the first channel part.

7. The heat sink of claim 6, wherein the first channel part includes:
a plurality of first channels disposed apart from each other in a first direction; and
a plurality of second channels disposed apart from each other in a second direction intersecting the first direction and communicating with the plurality of first channels.

8. The heat sink of claim 7, wherein the first entrance is located at a first intersection part at which each of the plurality of the first channels intersects one of the plurality of second channels.

9. The heat sink of claim 8, wherein the first entrance is provided as a plurality of first entrances disposed apart from each other in the first direction and the second direction at the first intersection part.

10. The heat sink of claim 7, wherein:
the second channel part includes a second port through which the fluid is introduced or discharged; and
the second port is disposed at one side or each of both sides of the second channel part.

11. The heat sink of claim 10, wherein vapor bubbles generated in the first channel part and the second channel part are discharged through the first port, the second port, or the entrance.

12. The heat sink of claim 10, wherein the second channel part includes:
a plurality of third channels disposed apart from each other in the first direction; and
a plurality of fourth channels disposed apart from each other in the second direction intersecting the first direction and communicating with the plurality of third channels.

13. The heat sink of claim 12, wherein a cross section of each of the first channel, the second channel, the third channel, and the fourth channel is formed in any one shape of a circular shape, an oval shape, and a polygonal shape.

14. The heat sink of claim 12, wherein the second entrance is disposed at a second intersection part at which each of the plurality of third channels intersects one of the plurality of fourth channels.

15. The heat sink of claim 14, wherein the second entrance is provided as a plurality of second entrances disposed apart from each other in the first direction and the second direction at the second intersection part.

16. The heat sink of claim 12, wherein:
the third channel includes a plurality of first pin fin parts disposed apart from each other in the second direction; and
the fourth channel includes a plurality of second pin fin parts disposed apart from each other in the first direction.

17. The heat sink of claim 5, wherein a diameter of the second entrance is smaller than a diameter of the first entrance.

18. The heat sink of claim 17, wherein the second entrance is provided as a plurality of second entrances in a range limited by the diameter of the first entrance.

19. The heat sink of claim 5, wherein:
the first entrance is provided in a first surface of the main body; and
a heat spreader is coupled to a second surface of the main body.
